(19) United States
(12) Patent Application Publication
(10) Pub. No.: US 2026/0005046 A1
(43) Pub. Date: Jan. 1, 2026

(54) MOLDING APPARATUS AND METHOD FOR MAKING AN ELECTRONIC PACKAGE

(71) Applicant: JCET STATS ChipPAC Korea Limited, Incheon (KR)

(72) Inventors: SangHoon LEE, Incheon (KR); SeungHyun LEE, Incheon (KR)

(21) Appl. No.: 19/253,934

(22) Filed: Jun. 29, 2025

(30) Foreign Application Priority Data
Jun. 28, 2024 (CN) 202410861168.5

(51) Int. Cl. H01L 21/67; H01L 21/56

(52) U.S. Cl. CPC H01L 21/67126; H01L 21/565

(57) ABSTRACT

Abstract

A molding apparatus and a method for making an electronic package are provided. The molding apparatus comprises: a top chase; a bottom chase matable with the top chase, wherein the top chase and the bottom chase define together a molding chamber for accommodating a package strip, and the molding chamber comprises a flow input configured to receive a mold fluid and a flow output configured to output the mold fluid after the mold fluid flows through the molding chamber and across the package strip in a flow direction substantially from the flow input to the flow output, wherein the molding chamber further comprises a flow control structure at or close to two side walls of the molding chamber relative to the flow direction to reduce a flow speed of the mold fluid close to the two side walls.

### TECHNICAL FIELD

The present application generally relates to semiconductor technology, and more particularly, to a molding apparatus and a method for making an electronic package.

### BACKGROUND OF THE INVENTION

Recently, with the growing demand for high performance, low cost and miniaturization of electronic devices, more and more electronic components and functions are being integrated into a single electronic package. High-density packaging is an advanced technology that integrates various functions, such as communication function, audio/video function, computing function, and/or the like, into one electronic package. In order to implement the high-density package units, interconnection structures, such as interposers (e-Bar, Cu post) and through mold via (TMV) structures, can be applied.

FIGS. 1A and 1B illustrate a top view and a cross-sectional view of a normal-density package unit 10, while FIGS. 1C and 1D illustrate a top view and a cross-sectional view of a high-density package unit 20. As shown in FIGS. 1A to 1D, compared with the normal-density package unit 10 shown in FIGS. 1A and 1B, the electronic package 10 shown in FIGS. 1C and 1D needs to be placed at a higher density in a high-density array, and various interconnection structures 22 may be mounted close to a marginal region of the package unit 20 for interconnection purpose. Therefore, a conventional mold chase design for the normal-density package unit 10, in which a minimum distance between a side wall of a molding chamber of a mold chase and a corresponding edge of the electronic package of the array is 1.535mm or so, may not be suitable for a strip of the high-density package units 20. Especially, voids and incomplete mold may occur to the high-density array if molded by the conventional mold chase.

Therefore, a need exists for improving the mold chase for high-density arrays.

### SUMMARY OF THE INVENTION

An objective of the present application is to provide a molding apparatus and a method for making an electronic package which may avoid the void and incomplete molding issue.

According to an aspect of the present application, a molding apparatus is provided. The molding apparatus comprises: a top chase; a bottom chase matable with the top chase, wherein the top chase and the bottom chase define together a molding chamber for accommodating a package strip, and the molding chamber comprises a flow input configured to receive a mold fluid and a flow output configured to output the mold fluid after the mold fluid flows through the molding chamber and across the package strip in a flow direction substantially from the flow input to the flow output, wherein the molding chamber further comprises a flow control structure at or close to two side walls of the molding chamber relative to the flow direction to reduce a flow speed of the mold fluid close to the two side walls.

According to another aspect of the present application, a method for making an electronic package is provided. The method comprises: placing a package strip in a molding chamber having a flow input, a flow output, side walls relative to a flow direction from the flow input to the flow output and a flow control structure at or close to the side walls; receiving a mold fluid at the flow input; directing the mold fluid towards the flow output of the molding chamber from the flow input such that the flow control structure reduces a flow speed of the mold fluid close to the side walls when the mold fluid flows across the package strip; and outputting the mold fluid at the flow output.

It is to be understood that both the foregoing general description and the following detailed description are exemplary and explanatory only and are not restrictive of the invention. Further, the accompanying drawings, which are incorporated in and constitute a part of this specification, illustrate embodiments of the invention and together with the description, serve to explain the principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A and 1B illustrate a top view and a cross-sectional view of a normal-density package unit, while FIGS. 1C and I D illustrate a top view and a cross-sectional view of a high- density package unit.

FIGS. 2A to 2C illustrate mold flow simulation results for a normal-density package strip in a conventional mold chase under different test conditions.

FIGS. 3A and 3B illustrate further the incomplete mold issue for a high-density package strip.

FIGS. 4A, 4B and 4C illustrate a molding apparatus according to an embodiment of the present application.

FIGS. 5A and 5B illustrate a molding apparatus according to another embodiment of the present application.

FIGS. 6A and 6B illustrate two mold flow simulation results for a high-density package strip in a mold chamber according to the two embodiments shown in FIGS. 4A to 4C and FIGS. 5A to 5B.

FIG. 7 illustrates a flowchart illustrating a method for naking an electronic package according to an embodiment of the present application.

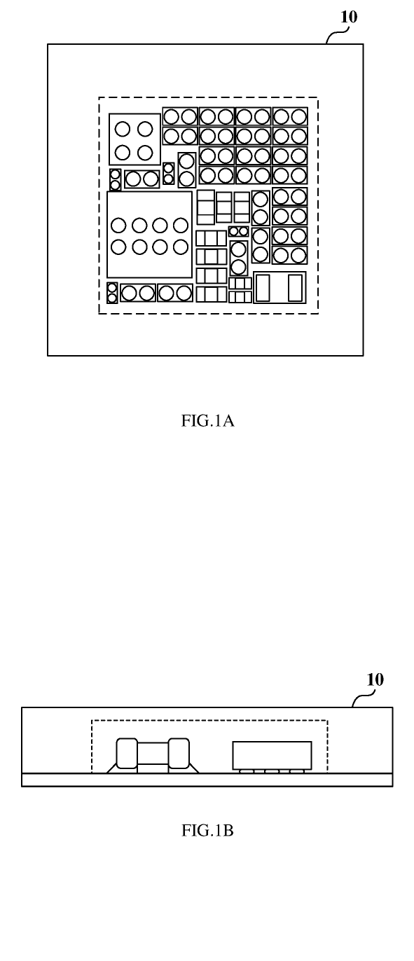

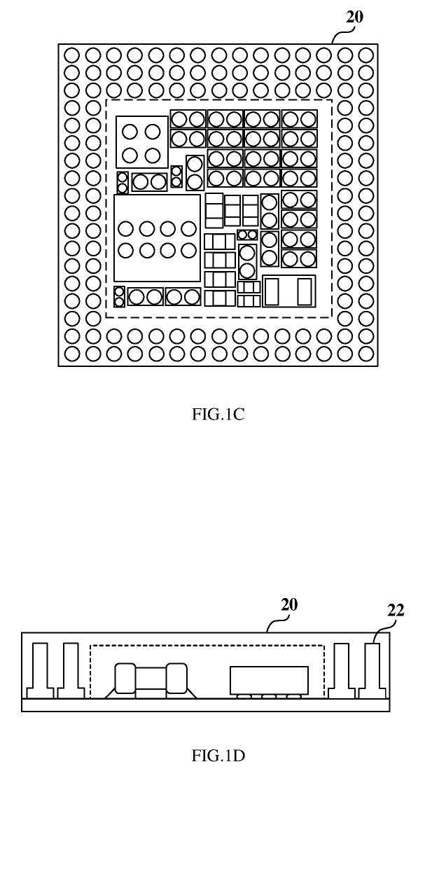

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of "or" means "and/or" unless stated otherwise. Furthermore, the use of the term "including" as well as other forms such as "includes" and "included" is not limiting. In addition, terms such as "element" or "component" encompass both elements and components including one unit, and elements and components that include more than one subunit, unless specifically stated otherwise. Additionally, the section headings used herein are for organizational purposes only and are not to be construed as limiting the subject matter described.

As used herein, spatially relative terms, such as "beneath", "below", "above", "over", "on"', "upper", "lower", "left", "right", "vertical", "horizontal", "side" and the lilke, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being "connected to" or "coupled to" another element, it may be directly connected to or coupled to the other element, or intervening elements may be present.

As aforementioned, void and incomplete mold issue may occur to package strips especially high-density package strips. Various experiments have been performed by the inventors of the present application to investigate reasons for these issues. It is unexpectedly noted by the inventors that the mold flow in a mold chase for the package strips results in the above issues.

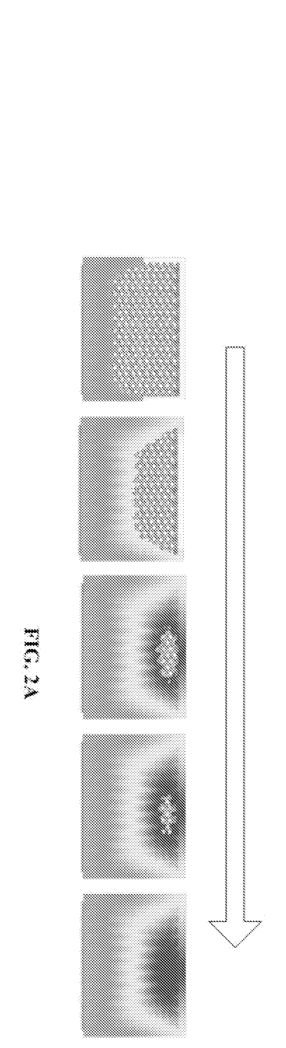

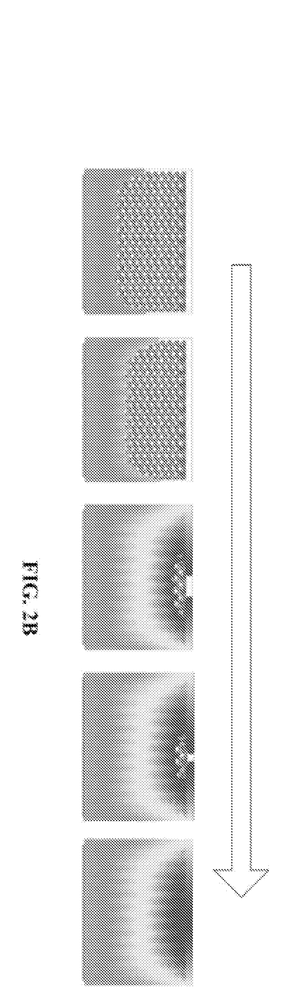

FIGS. 2A to 2C illustrate mold flow simulation results for a normal-density package strip in a conventional mold chase under different test conditions. In particular, FIG. 2A shows the simulation result under a condition where a distance between a side wall of a molding chamber and a corresponding edge of an electronic package strip is 4.059 min, FIG. 2B shows the simulation result under a condition where the distance between the side wall and the corresponding edge of the electronic package strip is 2.000mm, and FIG. 2C shows the simulation result under a condition where the distance between the side wall and the corresponding edge of the electronic package strip is 1.600 mm. As shown in FIGS. 2A to 2C, a mold fluid flows over a surface of the package strip and gradually occupies substantially the entire surface.

In particular, as can be seen from the simulation results shown in FIGS. 2A to 2C, a mold fluid in the molding chamber may exhibit a U-shaped leading edge, i.e., the mold fluid may have a higher flow speed adjacent to the side wall of the molding chamber compared to its flow speed at a central position. The non-uniform flow speed of the mold fluid in the molding chamber may produce a significant void at later stages of the molding process. There is no big issue for the molding process if it is used to mold normal-density package strips. However, if the conventional mold chase is directly applied in the molding process for the high- density package strips, such incomplete mold fluid such as epoxy molding compound may not be able to fully cover interconnection structures such as interposers (e-Bar, Cu post) and through molding via (TMV) structures mounted on the high-density package array or strip. These voids and the incomplete mold issue may bring significant defects such as electric static discharge (ESD) or short-circuit defects, which lowers significantly a yield of the high-density packages.

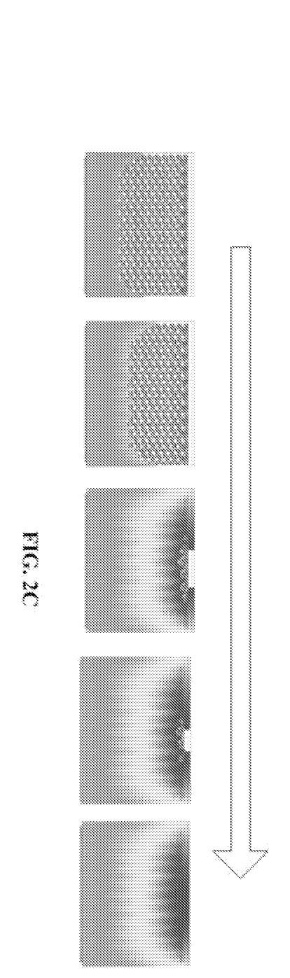

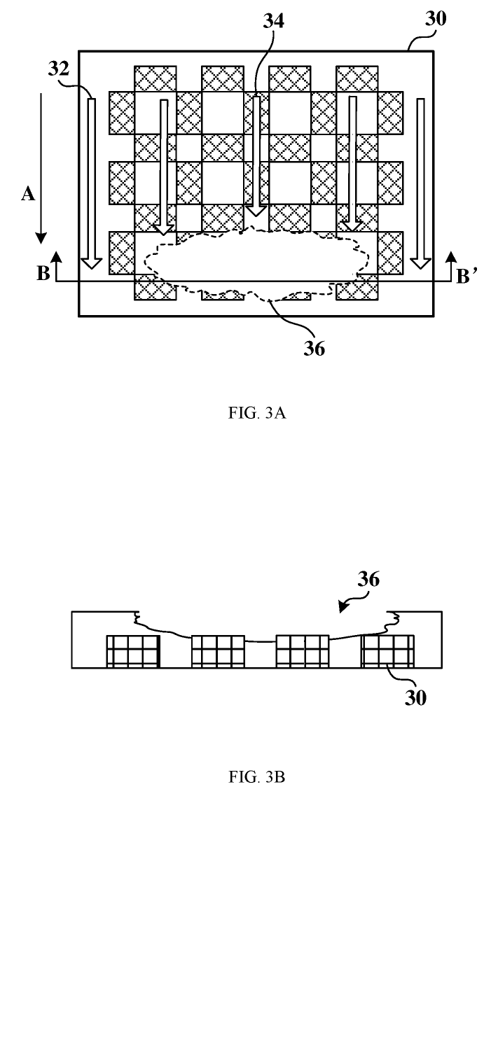

FIGS. 3A and 3B illustrate further the incomplete mold issue for a high-density package strip 30. In particular, FIG. 3A illustrates a top view of the high-density package strip 30, and FIG. 3B illustrates a cross-sectional view of the high-density package strip 30 along line BB'.

As shown in FIG. 3A, when a mold fluid is injected into a mold chase to encapsulate various electronic packages of the high-density package strip 30, in a flow direction A from a flow input to a flow output of the mold chase, the mold fluid may flow quicker in the marginal areas of the mold chase. That is, a portion 32 of the mold fluid flowing in the marginal area may reach the flow output earlier than the other portion 34 of the mold fluid flowing in the central area. As a result, air in the central area may be trapped in the mold fluid and cannot be exhausted through the flow output from the mold fluid, resulting in a void 36 close to the flow output of the mold chase.

In order to address the above issue, the inventors of the present application conceived a new molding apparatus with a flow control structure to avoid the incomplete mold issue. The flow control structure can be positioned at or close to side walls of a molding chamber of the molding apparatus to reduce or eliminate a non-uniform distribution of the flow speed of the mold fluid during the molding process. In this way, air may not be trapped in the mold fluid at later stage of the molding process, and thus will not produce the undesired voids in the resulting mold caps so formed.

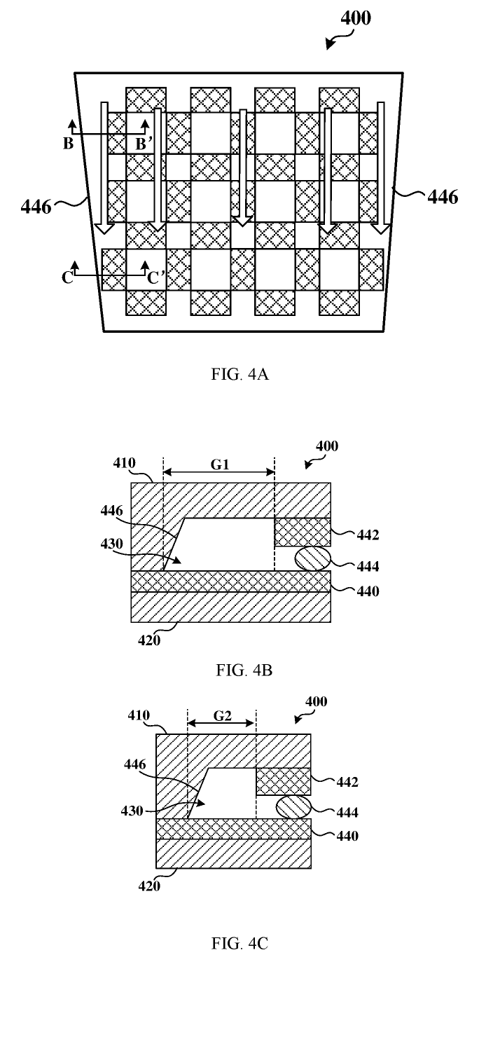

FIGS. 4A, 4B and 4C illustrate a molding apparatus 400 according to an embodiment of the present application. In particular, FIG. 4A is a top view of the molding apparatus 400, and FIGS. 4B and 4C are cross sectional views of a portion of the molding apparatus 400 along lines BB and CC in FIG. 4A.

As shown in FIGS. 4A and 4B, the molding apparatus 400 may include a top chase 410 and a bottom chase 420 matable with the top chase 410. The top chase 410 and the bottom chase 420 may define a molding chamber 430 for accommodating a package substrate 440. The molding chamber 430 includes a flow input (not shown) to receive a mold fluid and a flow output (not shown) to output the mold fluid after the mold fluid flows through the molding chamber 430. When the mold fluid flow through the molding chamber 430, it can flow across the package substrate 440, or particularly a surface of the package substrate, in a flow direction substantially from the flow input to the flow output. As such, a portion of the mold fluid may be attached on the package substrate. In the embodiment, a plurality of electronic components 442 such as semiconductor dice may be mounted on the package substrate 440 via respective sets of solder bumps 444 or other similar connection structures. The mold fluid can form a mold cap on the package substrate 440 which encapsulates the electronic components 442 and the solder bumps 444 and prevent from external contaminants and damages.

In the embodiment, the bottom chase 420 is shaped as a generally flat plate or platform, while the top chase 410 is shaped as a cover with side walls 446 extending from a main body. As such, the molding chamber 430 formed by the bottom chase 420 and the top chase 410 may have a shape generally defined by the inside of the top chase 410. Furthermore, the package substrate 440 may be placed on the bottom surface of the bottom chase 420, and thus be accommodated within the molding chamber 430. Although it is shown in FIGS. 4B and 4C the side walls 446 are inclined with respect to the bottom chase 420, in some alternative embodiments, the side walls 446 may be generally perpendicular to the bottom chase 420. During the molding process such as an injection molding process, the side walls 446 may be in contact with the mold fluid flowing within the molding chamber 430.

The molding chamber 430 may further include a flow control structure at or close to two side walls 446 of the molding chamber 430 relative to the flow direction of the mold fluid, to reduce a flow speed of the mold fluid close to the two side walls 446. The flow control structure may adopt various forms to control the flow speed of the mold fluid. In the embodiment, the flow control structure may be configured to have an angled shape relative to the flow direction, that is, a distance between the two side walls 446 of the molding chamber 430 decreases in the flow direction A. As shown in FIG. 4B which shows a cross section of the molding apparatus 400 at a position closer to the flow input of the molding chamber 430, the distance G1 from the side wall 446 to the electronic component 442 on the package substrate 440 is significantly greater than the distance G2 at a cross section of the molding apparatus 400 closer to the flow output of the molding chamber 430 which is shown in FIG. 4C.

As the distance between the two side walls 446 decreases, the flow speed of the mold fluid close to the side walls 446 may become slower due to a higher pressure of fluid. Such speed reduction may compensate for a difference in flow speed between the fluid flow close to the side walls 446 and the fluid flow at the center of the molding chamber 430 where the package substrate 440 may have various electronic components 442 mounted thereon that may reduce the flow speed of the mold fluid. In this way, a widthwise non-uniform distribution of the fluid flow closer to the flow output of the molding chamber 440 can be avoided, and thus, mold defects such as voids can be reduced or avoided.

In some embodiment, the distance G1 between each side wall 446 of the molding chamber 430 and a corresponding edge of the package strip placed in the molding apparatus 400 is at least 1.535mm. It should be noted that the edge of the package substrate 440 is the edge of an array of electronic components, rather than the edge of the package substrate 440. Furthermore, the distance G2 at the flow output between each side wall 446 and a corresponding edge of the package strip is narrower than the distance G l. A width of the distance G2 is smaller than 1.535mm, for example, may be 0.400mm, 0.200mm or even narrower. The distance G1 at the flow input may be configured substantially the same as that of a conventional mold chase.

In some alternative embodiments, the flow control structure may adopt other designs. As an example, in some embodiments, the flow control structure may use additional blocker(s) to impede the flowing of the mold flow, without changing the shape of the molding chamber.

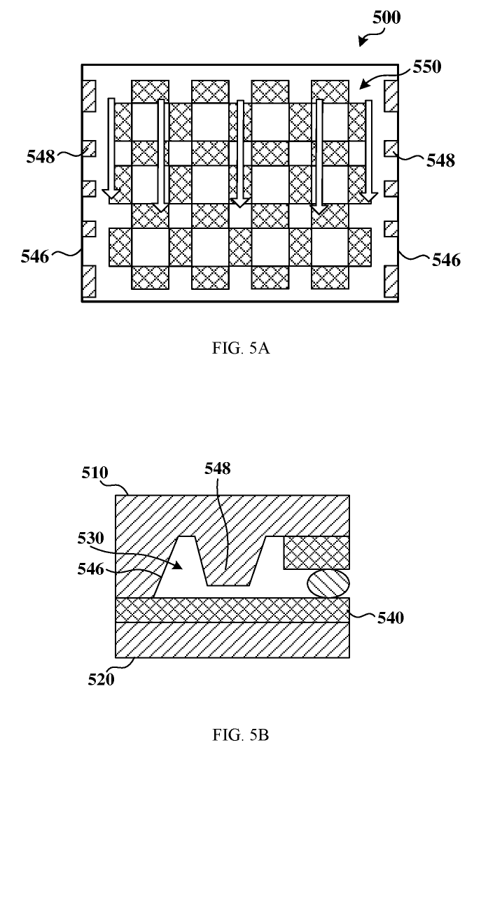

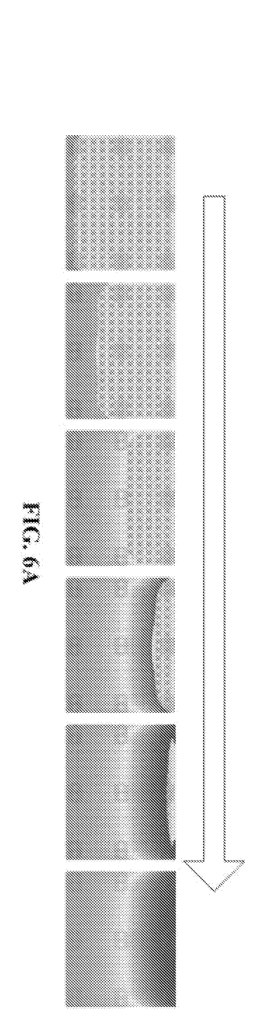

FIGS. 5A and 5B illustrate a molding apparatus 500 according to another embodiment of the present application. In particular, FIG. 5A illustrates a top view of the molding apparatus 500, and FIG. 5B illustrates a cross-sectional view of a portion of the molding apparatus 500.

As shown in FIGS. 5A and 5B, the flow control structure of the molding apparatus 500 may include at least one blocker 548 which protrudes to a molding chamber 530 defined by a top chase 510 and a bottom chase 520. As the at least one blocker 548 occupies a portion of the marginal region above a package substrate accommodated within the molding chamber 540, it may impede the flowing of the mold fluid close to the side wall 546. Similar as the embodiment shown in FIGS. 4A to 4C, the flow speed reduction can compensate for a difference in flow speed between the fluid flow close to the side walls 546 and the fluid flow at the center of the molding chamber 530. In this way, a widthwise non-uniform distribution of the fluid flow closer to the flow output of the molding chamber 540 can be avoided, and thus, mold defects such as voids can be reduced or avoided.

In particular, as shown in FIG. 5B, the at least one blocker 548 may be formed on the main body of the top chase 510 and extend downward towards to the bottom chase 520. But the blocker 548 is generally closer to the side wall 546 as it needs to occupy the gap between the side wall 546 and the package strip. In some alternative embodiments, the blocker 548 may be formed on the side walls 546 and extend horizontally along the surface of the package substrate 540. Also, in order to facilitate subsequent removal of the package strip from the top chase 510, the blocker 548 may have a conical shape. Preferably, the at least one blocker 548 and the top chase 510 may be formed integrally as a single piece. In the embodiment shown in FIG. 5B, there are five blockers 548 formed on each side wall in the molding chamber 530, however, another number of blockers 548 may be formed, such as three, four, six or even more. Also, a cross sectional area or a length into the molding chamber 530 of the blockers 548 may change, for example, increase when the blocker 548 gets closer to the flow output.

Similarly, although it is not shown in these figures, the at least one blocker may be formed on the bottom chase, close to each of the two side walls. In other words, the flow control structure may include, close to each of the two side walls, at least one blocker extending from a body portion of the bottom chase to the molding chamber.

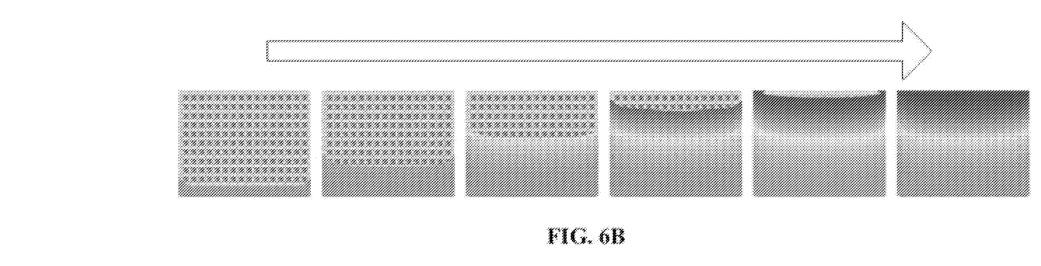

FIGS. 6A and 6B illustrate two mold flow simulation results for a high-density package strip in a mold chamber according to the two embodiments shown in FIGS. 4A to 4C and FIGS. 5A to 5B. As shown in FIGS. 6A and 6B, mold defects such as voids can be well improved.

In above explementary embodiments, the flow control structure implemented by angling the side wall of the molding chamber and the flow control structure implemented by at least one flow blocker are illustrated in different embodiments, these embodiments may be combined in a single embodiment. For example, the flow control structure may be configured such that a gap between a side wall of the molding chamber and a corresponding edge of the package strip decreases in the flow direction, and meanwhile, it may be further configured to dispose one or more flow blocker at or close to the side walls of the molding chamber.

Furthermore, those implementations of the flow control structure illustrated in the above embodiments are only exemplary, this application is not limited thereto. In other implementations, any flow control structure that is capable of deceasing a cross section of the molding chamber in the flow direction, or capable of reducing the flow speed of the mold fluid close to the side walls of the molding chamber, may also be applicable in this application.

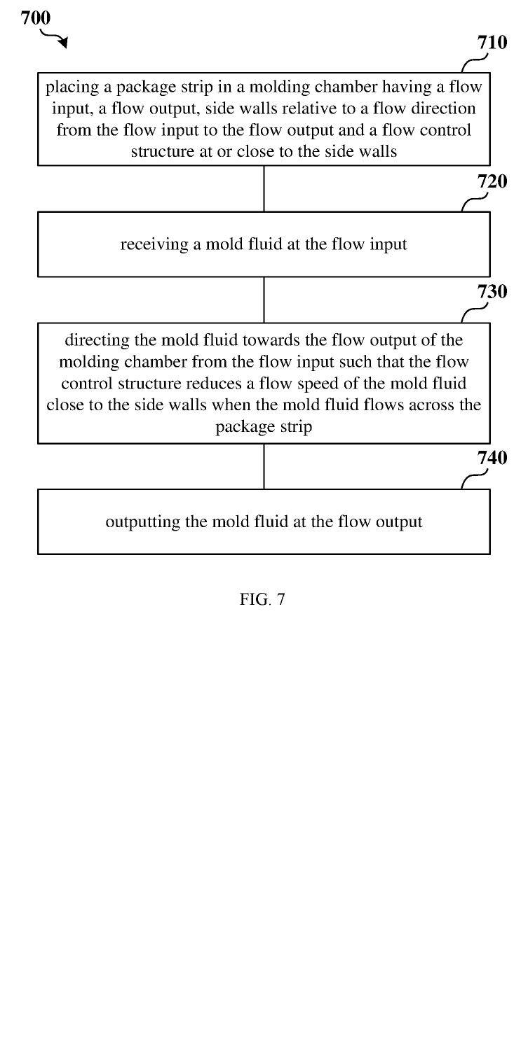

FIG. 7 illustrates a flowchart illustrating a method 700 for making an electronic package according to an embodiment of the present application.

Referring to FIG. 7, the method 700 may begin with block 710, a package strip may be placed in a molding chamber having a flow input, a flow output, side walls relative to a flow direction from the flow input to the flow output and a flow control structure at or close to the side walls. Then, at block 720, a mold fluid is received at the flow input, and at block 730, the mold fluid is directed towards the flow output of the molding chamber from the flow input such that the flow control structure reduces a flow speed of the mold fluid close to the side walls when the mold fluid flows across the package strip. At block 740, the mold fluid is output at the flow output. Functions and structures of above components including the molding chamber, the flow input and the flow output, and the side walls, have been illustrated in detail in above parts, the redundant description of them will be omitted herein for brevity.

The discussion herein included numerous illustrative figures that showed various portions of an electronic package and a method for making the same. For illustrative clarity, such figures did not show all aspects of each example assembly. Any of the example devices and/or methods provided herein may share any or all characteristics with any or all other devices and/or methods provided herein. It could be understood that embodiments described in the context of one of the devices or methods are analogously valid for the other devices or methods. Similarly, embodiments described in the context of a device are analogously valid for a method, and vice versa. Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A molding apparatus, comprising:
a top chase;
a bottom chase matable with the top chase, wherein the top chase and the bottom chase define together a molding chamber for accommodating a package strip, and the molding chamber comprises a flow input configured to receive a mold fluid and a flow output configured to output the mold fluid after the mold fluid flows through the molding chamber and across the package strip in a flow direction substantially from the flow input to the flow output,
wherein the molding chamber further comprises a flow control structure at or close to two side walls of the molding chamber relative to the flow direction to reduce a flow speed of the mold fluid close to the two side walls.

2. The molding apparatus of claim 1, wherein the flow control structure is configured such that a distance between the two side walls of the molding chamber decreases in the flow direction.

3. The molding apparatus of claim 1, wherein the package strip is disposed at a central position of the molding chamber in a widthwise direction of the molding chamber which is substantially perpendicular to the flow direction, and the flow control structure is configured such that a gap between a side wall of the molding chamber and a corresponding edge of the package strip decreases in the flow direction.

4. The molding apparatus of claim 3, wherein a width of the gap at the flow output is smaller than 1.535mm.

5. The molding apparatus of claim 1, wherein the flow control structure comprises, on each of the two side walls, at least one blocker protruding from the side wall to the molding chamber.

6. The molding apparatus of claim 5, wherein the side walls are a portion of the top chase, and the at least one blocker and the top chase are formed integrally as a single piece.

7. The molding apparatus of claim 1, wherein the flow control structure comprises, close to each of the two side walls, at least one blocker extending from a body portion of the top chase or the bottom chase to the molding chamber.

8. The molding apparatus of claim 1, wherein the flow control structure is configured such that a cross section of the molding chamber decreases in the flow direction.

9. The molding apparatus of claim 1, wherein the flow control structure is configured to reduce the flow speed of the mold fluid close to the two side walls such that voids of the mold fluid at or close to the flow output is avoided.

10. A method for making an electronic package, the method comprising:
placing a package strip in a molding chamber having a flow input, a flow output, side walls relative to a flow direction from the flow input to the flow output and a flow control structure at or close to the side walls;
receiving a mold fluid at the flow input;
directing the mold fluid towards the flow output of the molding chamber from the flow input such that the flow control structure reduces a flow speed of the mold fluid close to the side walls when the mold fluid flows across the package strip; and
outputting the mold fluid at the flow output.

11. The method of claim 10, wherein the flow control structure is configured such that a distance between the side walls of the molding chamber decreases in the flow direction.

12. The method of claim 10, wherein the package strip is disposed at a central position of the molding chamber in a widthwise direction of the molding chamber which is substantially perpendicular to the flow direction, and the flow control structure is configured such that a gap between a side wall of the molding chamber and a corresponding edge of the package strip decreases in the flow direction.

13. The method of claim 12, wherein a width of the gap at the flow output is smaller than 1.535mm.

14. The method of claim 10, wherein the flow control structure comprises, on each of the side walls, at least one blocker protruding from the side wall to the molding chamber.

15. The method of claim 14, wherein the side walls are a portion of the top chase, and the at least one blocker and the top chase are formed integrally as a single piece.

16. The method of claim 10, wherein the flow control structure comprises, close to each of the side walls, at least one blocker extending from a body portion of the top chase or the bottom chase to the molding chamber.

17. The method of claim 10, wherein the flow control structure is configured such that a cross section of the molding chamber decreases in the flow direction.

18. The method of claim 10, wherein the flow control structure is configured to reduce the flow speed of the mold fluid close to the side walls such that voids of the mold fluid at or close to the flow output is avoided.
